(19) United States
(12) Patent Application Publication
(10) Pub. No.: US 2007/0192661 A1
(43) Pub. Date: Aug. 16, 2007

(54) Automatic Test Equipment (ATE) Realized Through Sharing Same Memory Space by Instruction Data and Vector Data

(76) Inventors: Edward C. Chang, San Francisco, CA (US); Meimei Chang, San Francisco, CA (US); Deirdre McGlashan, San Francisco, CA (US); Derek Chang, San Francisco, CA (US)

Correspondence Address: WPAT, PC;INTELLECTUAL PROPERTY ATTORNEYS, 2030 MAIN STREET, SUITE 1300, IRVINE, CA, 92614, US

(21) Appl. No.: 11/550,748

(22) Filed: Oct. 18, 2006

(30) Foreign Application Priority Data
Feb. 16, 2006 (TW) 095105217

(51) Int. Cl. G01R 31/28

(52) U.S. Cl. 714/738

(57) ABSTRACT

An improved Automatic Test Equipment (ATE) in which Instruction Memory and a Vector Memory are combined together into a tester pattern memory in order to share the same memory space. As such, reducing the memory, size, and cost of the Automatic Test Equipment.

### BACKGROUND OF THE INVENTION

1. Field of the Invention

The present invention relates to an improved automatic test equipment (ATE), and in particular to an improved automatic test equipment (ATE) realized through sharing the same memory space by Instruction Data and Vector Data.

2. The Prior Arts

When the device and equipment testing began to automate in the 60s, the information (Vector Data) used for testing the DUT (Device Under Test) was stored inside the computer. The first generation of ATE (Automatic Test Equipment) is shown in FIG. 1. As shown in FIG. 1, the Automatic Test Equipment (ATE) 10 is composed of a plurality of 32-pin blocks 14 on PC Boards, a programmable level driver and comparator 17, and a computer interface 16. The registers 15 are contained in the 32-pin blocks. The Device Under Test (DUT) 13 to be tested is disposed outside ATE. In this configuration, each of the respective Printed Circuit Board contains 32 pins as blocks. 32 pin blocks are chosen for ease of explanation as an example, but it could also be 16, 64, or 96 pin blocks. In operation, the computer sends Vector Data to a 32 bit register 15 to a PC Board until all the Boards receive all the Vector Data, then a command is sent by the computer to gate all the Vector Data out to the programmable drivers and comparators 17 as shown in FIG. 1A (Cycle #1 Data). In turn, the programmable drivers deliver the information with the correct voltage levels to the DUT. When the DUT outputs information, the computer turns off the programmable driver and lets the comparators send the information back to the PC Board to be compared with the information in the registers. As shown in FIG. 1A, a good ‘1’ level has to be higher than the cmpH and a good ‘0’ has to be lower than the cmpL. Otherwise the test fails. Executing Vector Data through registers is slow.

The second generation ATE system developed and as shown in FIG. 2 is realized by replacing the registers 15 in FIG. 1 with a Local Memory 22. As shown in FIG. 2, the Automatic Test Equipment (ATE) 20 is composed of a plurality of 32-pin blocks 24, a plurality of local memories 22, a memory controller 28, a programmable level driver and comparator 27, and a computer interface 26. A Device Under Test (DUT) 23 to be tested is disposed outside ATE. The name of Local Memory is also referred to as Vector Memory or Pattern Memory by different manufacturers. A Memory Controller 28 provides addresses to sequence the data out from the Local Memory as shown in FIG. 2. The first two generation ATE systems do not have the capabilities of formatting waveforms and timing control within a test cycle. The data comes up either high or low for the entire test cycle.

The third generation ATE system is shown in FIG. 3. As shown in FIG. 3, the Automatic Test Equipment (ATE) 30 includes: a memory address 31, a plurality of 32-pin blocks 32, a processor 39, a memory controller 38, a timing module 35, a waveform formatting circuit & comparison circuit 36, and a programmable level driver and comparator 37. A Device Under Test (DUT) 33 to be tested is disposed outside ATE. The third generation ATE shown in FIG. 3 is much more advanced and sophisticated, since Instruction Memory 31 was added to the Memory Controller 38. The Instruction Memory 31 and the Memory Controller 38 together become a Processor 39 as shown in FIG. 3. The Processor works just like a computer except that it does not manipulate the memory data. It just controls the sequence of addresses so that the Vector Memory data can be reused many times as specified by the instructions. For example, a repeat instruction will keep the address at the same position to repeat the Vector Data by the instruction field and the number of times of repeats are specified in the data field in the Instruction memory of the Processor 39. The memory inside the Processor is referred to as Control Memory or Instruction Memory 31. In addition to the sophisticated Memory Controller, a timing generator 35 is added to each pin to control the time of data rising and falling in a test cycle as shown in FIG. 3A, turning on and off of the programmable Driver and strobing the DUT output at the appropriate time. Moreover, the waveform Formatters 36 are also added to each pin to control the shape of the wave to the DUT. FIG. 3B shows the content of the Instruction Memory 31 and the Vector Memory 32 as an example. The Instruction Memory operates simultaneously with the Vector Memory. As an example, if there is no Instruction, the Instruction Memory is filled with all ‘0’ which is an NOP (No Operation Instruction). As shown at the left side of FIG. 3B, the Instruction Memory is filled with aaaaaaaaaa . . . aaa as a repeat instruction and the data word bbbbbbbbb specifies the number of times that is repeating. When data word counts to zero, then the address will increment to the next location which is an NOP. As a result the content in Tester Pin Data in line with the repeat instruction will repeat the same data to the DUT as the same number of time as the repeat instruction. For a jump instruction, the instruction word is filled with ccccccccc . . . cc and the data word ddddddddd specifies the location the address should jump to and so forth. At the right side of the FIG. 3B, the Vector Memory shows 5 bits for each tester pin as an example. The 5 bits Vector Memory for each pin controls the drive data, turning on and off of the programmable driver, masking the DUT output (do not compare), comparing a High ‘Z’ level or active level etc. Some ATE manufacturers use 3 or 4 bits per pin. For a high pin count and high speed (above 100 Mhz) ATE system, FIG. 3 will have a problem of sending addresses to all the PC Boards that require the addresses to arrive at all PC Boards almost at the same time.

To alleviate the pain and burden of distributing the massive addresses lines, the newer generation ATE Systems use parallel processing technique. Several processors are running simultaneously to address fewer PC Boards. In fact, most ATE manufacturers put one processor on each PC Board as shown in FIG. 4 and FIG. 4A. Only a few clock lines are needed to be well controlled as shown in FIG. 4A instead of controlling the massive address lines. As an example, FIG. 4A shows each 32 pin block as a PC Board. As shown in FIG. 4, the automatic test equipment (ATE) 40 includes a plurality of: Control memory and addresses 41, 32-pin block memories 42, timing modules 45, waveform formatters 46, processors 49, and a programmable level driver and comparator 47. A Device Under Test (DUT) 43 to be tested is disposed outside ATE.

### SUMMARY OF THE INVENTION

In view of the shortcomings and drawbacks of the prior art, the objective of the present invention is to provide an improved automatic test equipment (ATE) realized through sharing the same memory space by Instruction Data and Vector Data, which can be used to reduce the tester size and cost of the automatic test equipment and hence lower the production cost of the automatic test equipment.

To achieve the above-mentioned objective, the present invention provides an improved automatic test equipment (ATE) realized through sharing the same memory space by the Instruction Data and the Vector Data. In the design of the present invention, the control circuit of the Instruction Memory and the control circuit of the Vector Memory in the case of prior art, are combined and put into one ASIC as Pin Module in the present invention as an example. The combined memory thus obtained is referred to as Tester Pattern Memory. Moreover, one or more bits are added to the Tester Pattern Memory to identify the content in this memory whether it is a Vector Memory or Instruction Memory During execution of a functional test, supposing line 1 is a Vector Data because its identity bit is not on. Its content is sent to the Pin Data Register and the Storage Element in Processor. By storing ‘0’ in the Storage Element in Processor, that indicates it is a NOP (no operation instruction). In the design of the present invention, the Storage Element in the Processor could be a single level register, FIFO or a dual port memory. Moreover, assuming that the identity bit for Line 2 is ‘1’, then Line 2 is sent to the Storage Element in the Processor. The rest of the lines can be sent to the Storage Element in Processor or the Pin Data Register depending on the value of the identity bit in a similar manner, as such resulting in making the PC Board smaller in size and reducing the footprint of the tester. Thus the merit and advantage of the present invention is the reduction of memory components required and hence the reduction of cost and size of the Automatic Test Equipment (ATE).

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram of an automatic test equipment (ATE) of the prior art;

FIG. 1A is the waveform of Vector Data transmitted to the programmable driver and comparator as shown in the ATE of FIG. 1;

FIG. 2 is a schematic diagram of another automatic test equipment (ATE) of the prior art;

FIG. 2A is the waveform of Vector Data and Instruction Data transmitted in the ATE of FIG. 2;

FIG. 3 is a schematic diagram of still another automatic test equipment (ATE) of the prior art;

FIG. 3A is the waveform of Data. Timing, Final Drive, Final Compare, DUT output, and Strobe Timing transmitted inside the ATE of FIG. 3;

FIG. 3B is the memory layout of the Control Memory and Pin Data Memory of the ATE of FIG. 3;

FIG. 4 is a schematic diagram of still another automatic test equipment (ATE) of the prior art;

FIG. 4A is a schematic diagram of the distributed 32-pin block memory of the ATE of FIG. 4;

FIG. 5 is a schematic diagram of an improved automatic test equipment (ATE) according to an embodiment of the present invention;

FIG. 5A is a memory layout for the distributed 16-pin block memory used in the ATE of FIG. 5;

FIG. 6 shows an example of Instruction and Pin Data executed through Register in the ATE of FIG. 5;

FIG. 7A is the distributed parallel processor ATE Test System according to prior art; and

FIG. 7B is the distributed parallel processor ATE Test System according to present invention.

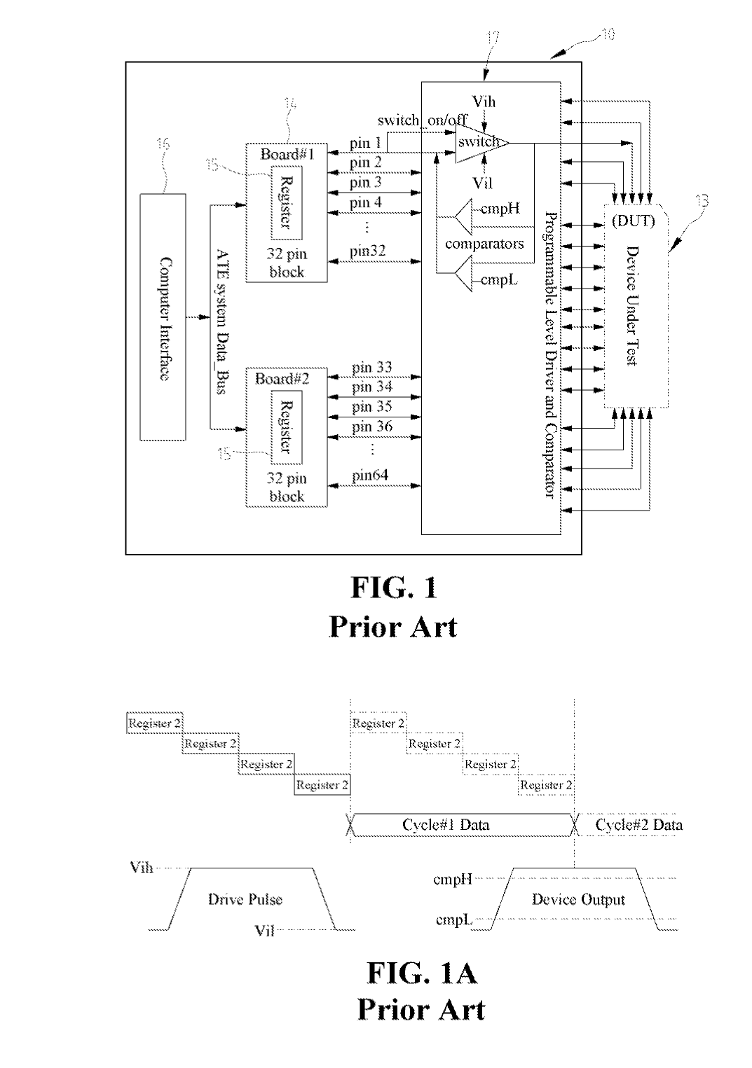

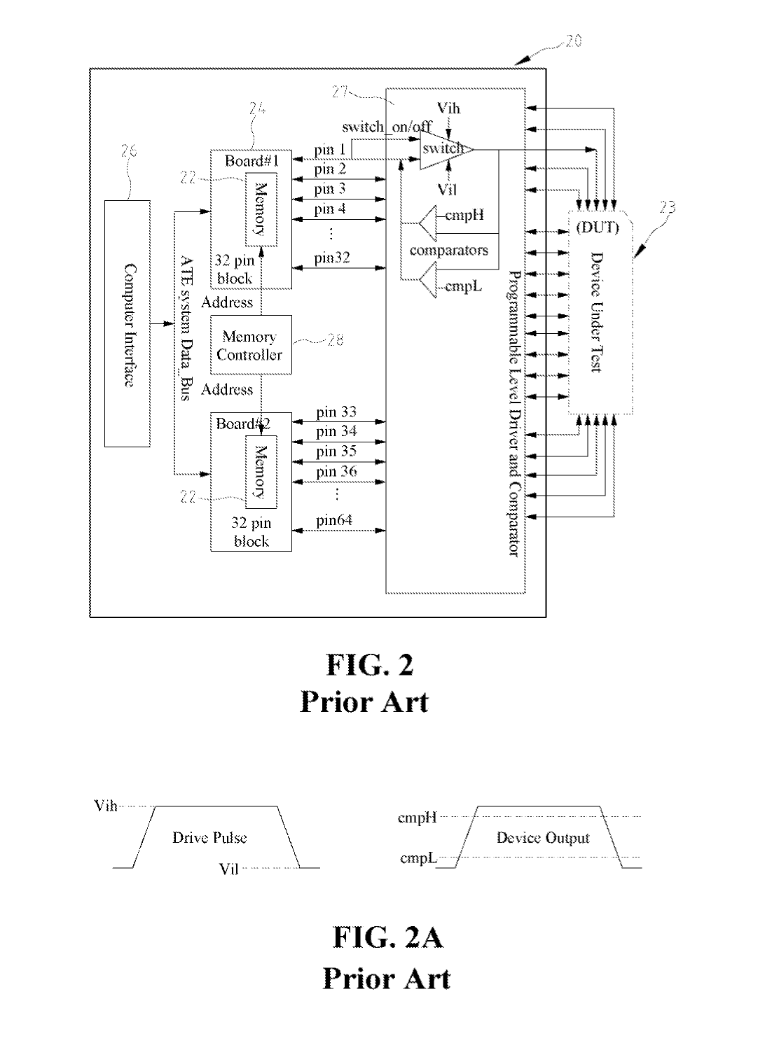

### DETAILED DESCRIPTION OF THE PREFERRED EMBODIMENT

The purpose, construction, features, functions and advantages of the present invention can be appreciated and understood more thoroughly through the following detailed description with reference to the attached drawings.

In the following illustrations, the improved automatic test equipment (ATE) realized through sharing the same memory space by Instruction Data and Vector Data of the present invention will be described in detail with reference to the attached drawings.

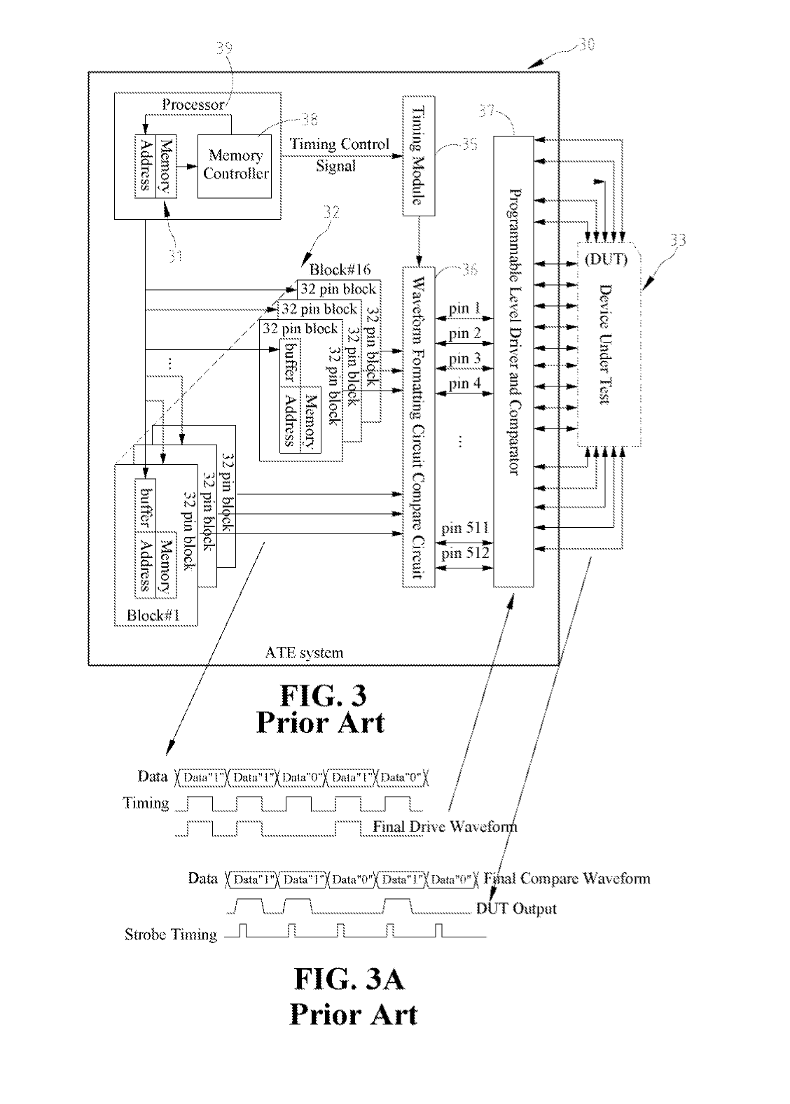

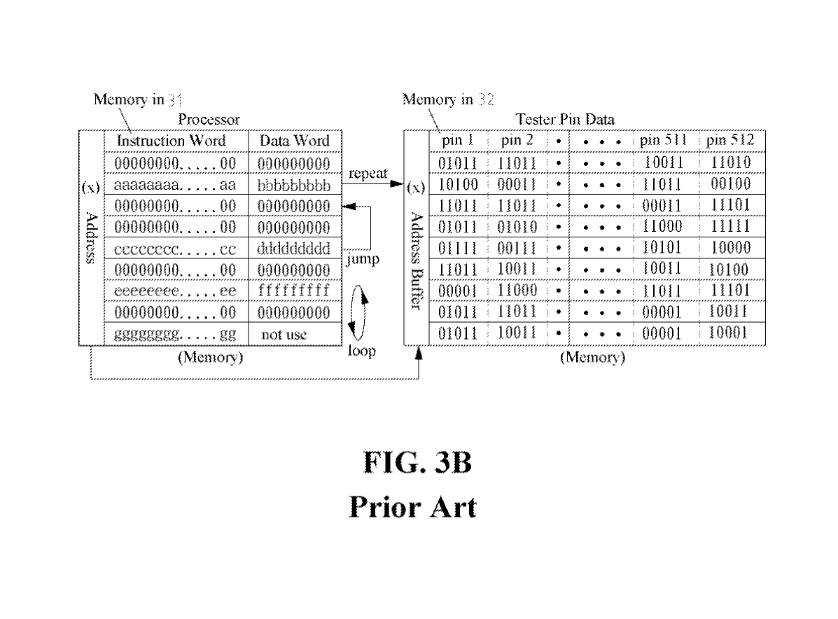

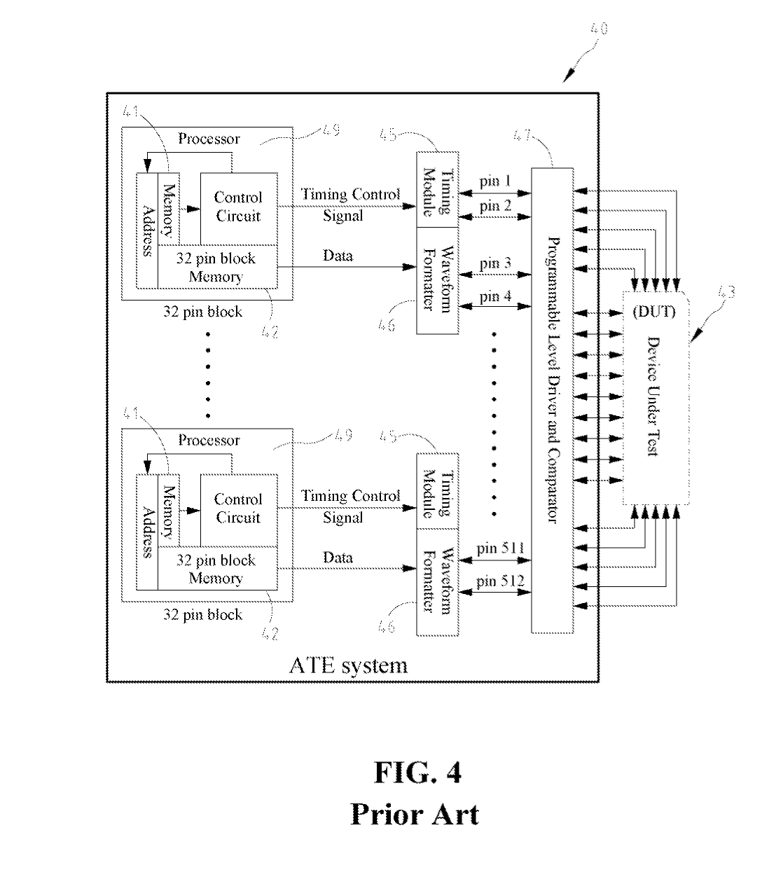

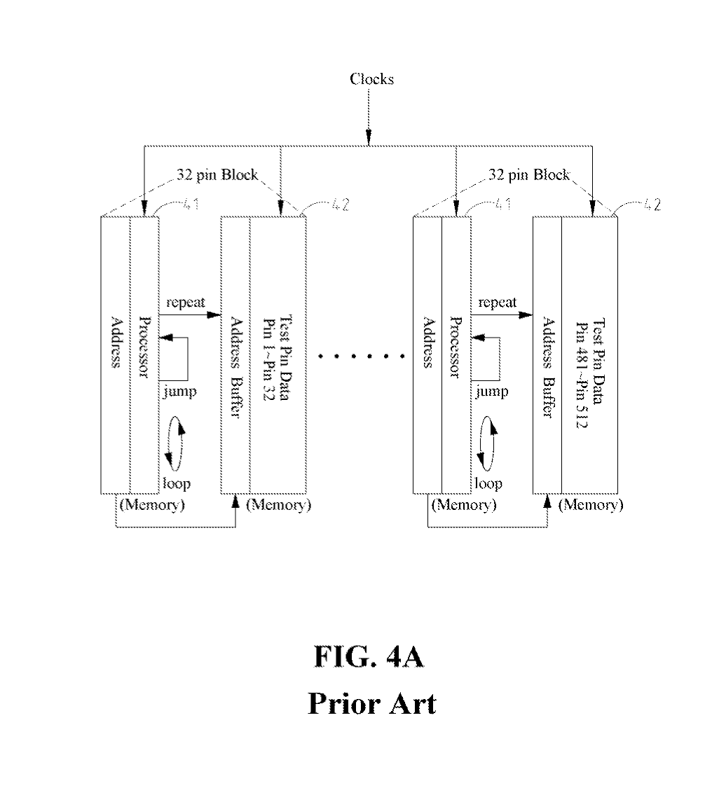

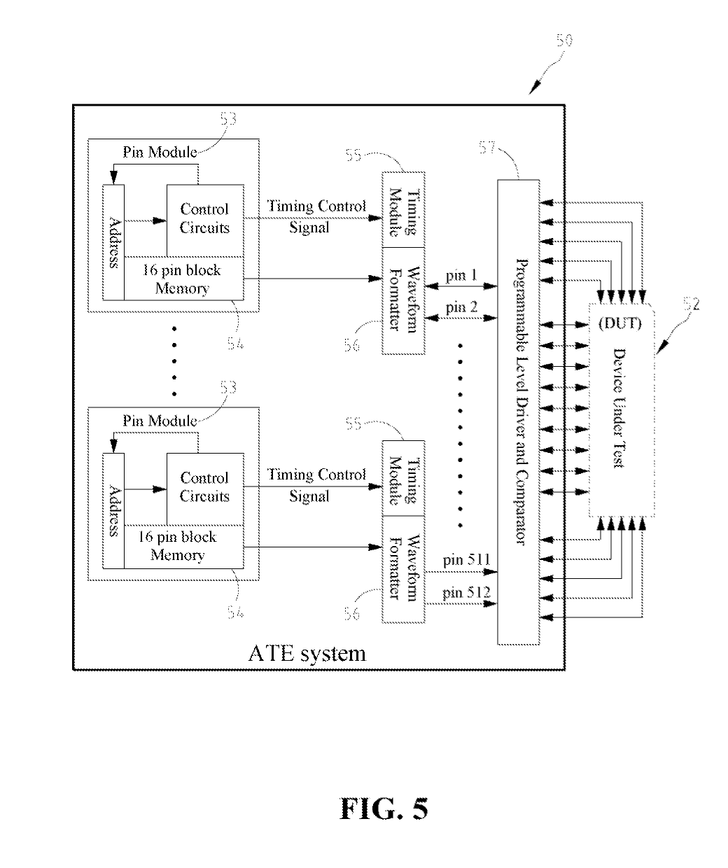

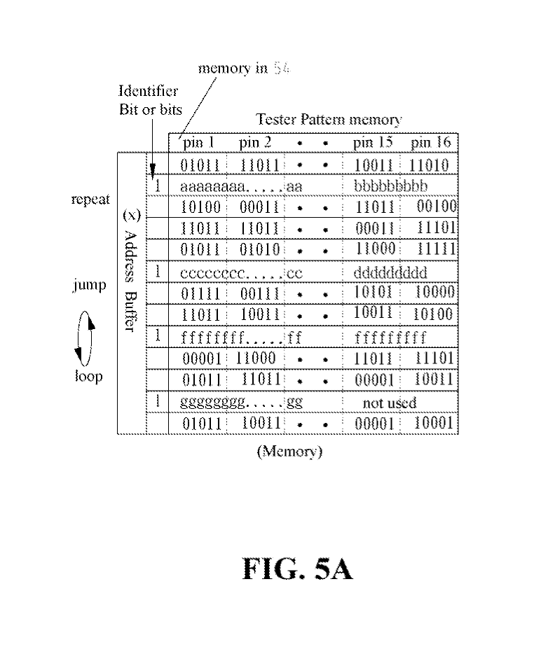

Firstly, please refer to FIGS. 5 and 5A. FIG. 5 is a schematic diagram of a distributed parallel automatic test equipment (ATE). FIG. 5A is a schematic diagram of the 16 pin block memory used in FIG. 5 according to an embodiment of the present invention. A Device Under Test (DUT) 52 to be tested is disposed outside ATE. Since the Vector Memory is absolutely required to provide data to the DUT, it is possible to put the Instruction Memory 31 combined with the Vector Memory 32 in FIG. 3B. The Control circuit for the Instruction Memory and the Vector Memory control circuit can be put into one ASIC as shown in FIG. 5 as Pin module 53 as an example. The combined memory now is referred to as 16 Pin Block memory 54 as shown in FIG. 5 and FIG. 5A. One or more bits are added to the Tester Pattern memory 54 as shown in FIG. 5A to identify the content in the Tester Pattern memory if it is a Vector or it is an Instruction.

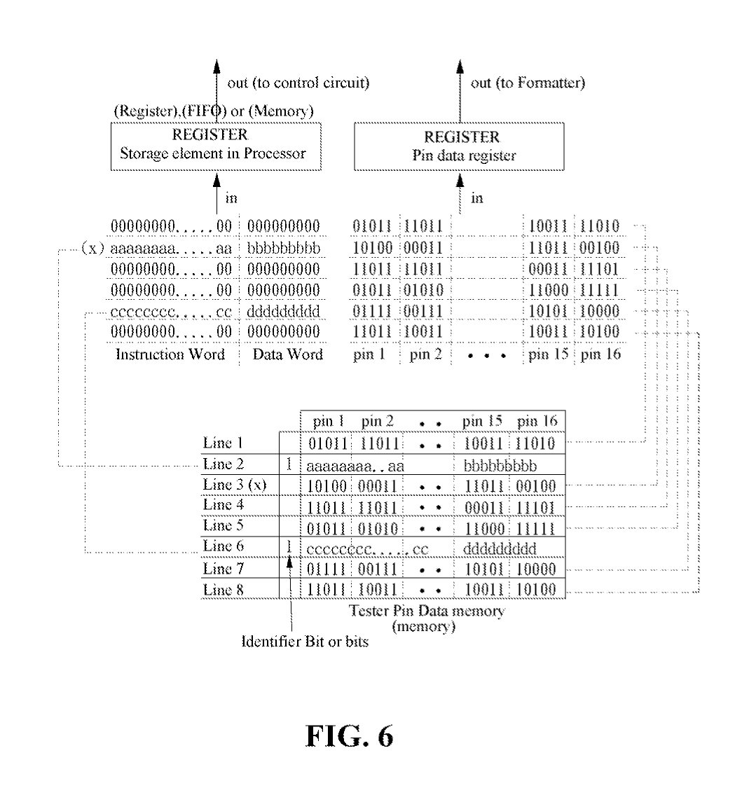

Moreover, refer to FIG. 6 for a memory layout for Storage element in Processor, Pin data register, and Tester Pin Data Memory utilized in executing the automatic testing according to an embodiment of the present invention. As shown in FIG. 6, during execution of a functional test, line 1 is Vector Data because the identity bit is not on. Its content is sent to the Pin data register and the Storage element in Processor on the right side is stored with ‘0’. By storing ‘0’ in the Storage element in Processor, that signifies it is a NOP (no operation instruction). The Storage Element in the Processor could be a single level register, FIFO or a dual port memory. Furthermore, Line 2 is sent to the Storage element in the Processor because the identity bit is a ‘1’, and Line 3 is sent to the Pin data register. Assuming that Line 2 is a repeat instruction and it will operate on the Line 3 data until the data field of the instruction bbbbbbbbb counts down to ‘0’. Lines 4 and 5 are Vector Data and they are sent to the Pin Data Register. Line 6 is an Instruction Word and is sent to the Storage Element in the Processor. Lines 7 and 8 are Vector Data and are sent to the Pin Data Register. The final result of FIG. 6 in the end is of the similar pattern as shown in FIG. 3B.

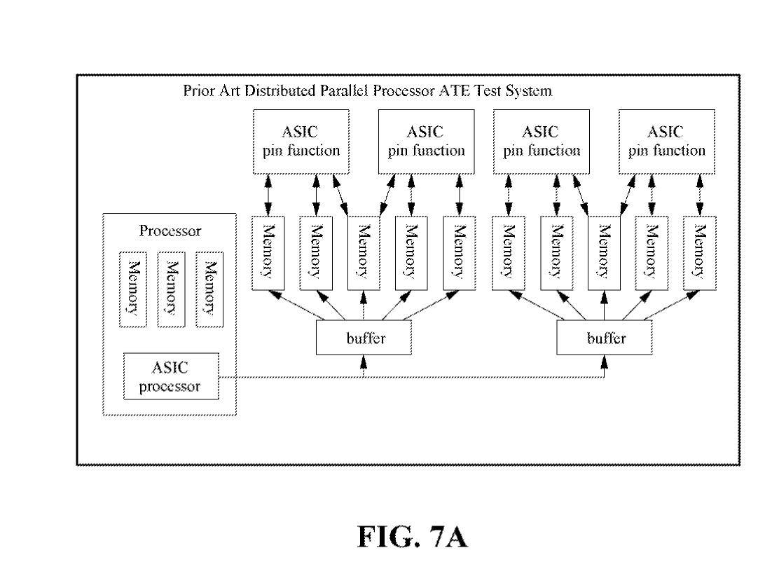

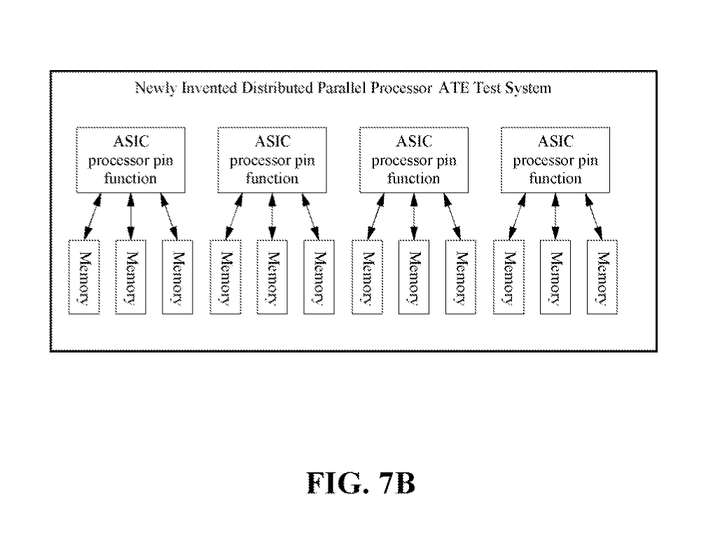

Furthermore, please refer to FIGS. 7A and 7B. FIG. 7A is a schematic diagram of the distributed parallel processor ATE Test System according to prior art. FIG. 7B is a schematic diagram of the distributed parallel processor ATE Test System according to the present invention. As shown in FIG. 7A, an ASIC is provided for the control circuit and the memories as Instruction Memory. The advantage of the present invention is evident from FIGS. 7A and 7B. As shown in FIG. 7B, the four ASIC's together with the memories may constitute a small ATE Tester by itself. These four small testers may run as an individual Tester or run simultaneously as a large Tester. The pin count of the Tester depends on the number of the PC boards. Comparing FIGS. 7A and 7B, the reduction of PC Board area can make the PC Board smaller in size.

Therefore, the result of making the PC Board smaller in size will reduce the footprint of the tester. From the user point of view, it is a cost reduction for using less footage of floor space. In addition to being smaller in size, it also achieves more cost saving by using fewer memory devices.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements that are within the scope of the appended claims.

What is claimed is:

1. An improved automatic test equipment (ATE), comprising:
an instruction memory; and
a vector memory;
wherein, the instruction memory and the vector memory share the same memory space in ATE, thus forming a tester pattern memory and sharing information in the ATE system, as such reducing the tester size and cost of ATE.

2. The improved automatic test equipment (ATE) as claimed in claim 1, wherein one or more bits are utilized in the Tester Pattern Memory as an identifier to differentiate it between a Vector Word and an Instruction Word.
